(19) United States
(12) Patent Application Publication
(10) Pub. No.: US 2024/0424791 A1
(43) Pub. Date: Dec. 26, 2024

(54) PROCESS FOR AN IPC COATING

(71) Applicant: FUJIFILM DIMATIX, INC., Lebanon, NH (US)

(72) Inventors: Shane Boyd, Lebanon, NH (US); Sean Cahill, Lebanon, NH (US); Kenichiro Tamaki, Lebanon, NH (US); Hiroshi Komatsu, Lebanon, NH (US); Eric Sanjuan, Lebanon, NH (US)

(21) Appl. No.: 18/212,607

(22) Filed: Jun. 21, 2023

(51) Int. Cl. B41J 2/16; C23C 16/40; C23C 16/455; C23C 16/56

(52) U.S. Cl. CPC B41J 2/164; B41J 2/1606; C23C 16/405; C23C 16/45525; C23C 16/56

(57) ABSTRACT

An inkjet printer printhead, member thereof, or other component has an internal cavity that has a protective coating. Further surfaces of the component may have the protective coating. To make the protective coating, a target thickness for a film of HfO₂ (hafnia) is selected, that will avoid formation of pinholes, thin spots and nodule growth. Using atomic layer deposition (ALD), with the processing adjusted for the target thickness, the film of HfO₂ is deposited as a conformal layer on the component, including on a surface of the internal cavity, to form a coated component. A non-wetting coating can be included over the film of HfO₂.

### BACKGROUND

Printer ink used in inkjet printers can be acidic or alkaline or a strong solvent which can cause cumulative damage and limit operating lifespan of printheads and other components of these machines. The printhead itself often has multiple components, including integrated circuit dies, microelectromechanical system (MEMS) dies, piezoelectric transducers, a head mount with internal chambers for ink, nozzles, etc. The various components are made of various construction materials (e.g., processed integrated circuit dies, processed microelectromechanical dies, plastics, metals) and assembly materials (e.g., a bonding material (e.g., solder, glue, adhesive, epoxy, etc.), fasteners, etc.), each of which imposes constraints on what can be done to protect the components from degradation resulting from exposure to printer ink, and perhaps other acid or alkaline or strong solvent liquids (e.g., during manufacture, cleaning or refurbishing). For example, solvent inks may also have detrimental effects on epoxy interfaces or on the epoxy/glues themselves. Therefore, there is an ongoing need in the art for improvements in component protection and operating lifespan of printheads and other components of inkjet printers, which may also benefit further components of further machines.

### SUMMARY

Processes and methods for making an article, or material thereof, with a protective coating are disclosed. In some embodiments, the method of making a material for an article, comprising: providing a component of a machine, wherein the component has at least one internal cavity accessible for processing, and wherein the component is to be exposed to an acid liquid, an alkali liquid, or another liquid that chemically attacks the component during usage of the machine; selecting a target thickness for a film of HfO2 that will avoid formation of pinholes, thin spots and nodule growth; and using atomic layer deposition (ALD) with the processing adjusted for the target thickness, depositing the film of HfO2 as a conformal layer on the component, including on a surface of the at least one internal cavity, to form a coated component, wherein the material comprises the deposited film of HfO2 as a protective coating.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIGS. 1A-1E depict components of an inkjet printer, as suitable for protective coating processes and materials described herein in various embodiments.

FIG. 1A depicts a head mount, which is a component of a printhead.

FIG. 1B depicts a MEMS die attached to a carrier, with ICs mounted to the MEMS die, as a component of a printhead.

FIG. 1C depicts a printhead, which is built up through assembly including components depicted in FIGS. 1A and 1B, as a component of an inkjet printer.

FIG. 1D depicts a cross section view of an example printhead, which is made of layers that define an internal cavity and a nozzle.

FIG. 1E depicts a cross section view of a further example printhead, which is made of layers that define an internal cavity and a nozzle.

FIG. 2A depicts a coating of HfO₂ on a component, in an embodiment.

FIG. 2B depicts a non-wetting coating on top of a coating of HfO₂ on a component, in an embodiment.

FIG. 2C depicts a multi-film coating on a component, in an embodiment.

FIGS. 3A-3D depict a cross section view of various components with a coating of HfO₂ on the component including coating an internal cavity, in embodiments.

FIG. 3A depicts a cross section view of a body that has an internal cavity exposed through a passage for processing, with a conformal coating of HfO₂.

FIG. 3B depicts a cross section view of a body that has an internal cavity, for example a passage exposed for processing, with a conformal coating of HfO₂.

FIG. 3C depicts a cross section view of a body that is built up by assembling two bodies to each other, and which has an internal cavity exposed for processing, with a conformal coating of HfO₂.

FIG. 3D depicts a cross section of a body that is built up by assembling two bodies to each other with glue or other bonding material, with a conformal coating of HfO₂

FIGS. 4A-4C depict a body that has an electrical contact region, in embodiments.

FIG. 4A depicts a body that has an electrical contact pad with gold atop another metal.

FIG. 4B depicts a cross section view of the embodiment in FIG. 4A, with a conformal layer of HfO₂ on the surface of the body, including over the electrical contact region, and a mask defining a selective removal region.

FIG. 4C depicts a cross section view of the embodiment in FIG. 4A, after further processing since the cross section view in FIG. 4B, showing selective removal of a portion of the HfO₂ in the electrical contact region, with partial removal of a portion of the gold on the electrical contact pad.

FIG. 5 depicts a flow diagram for an embodiment of a method of making a protective coating for a component, which can be practiced using embodiments described herein.

FIG. 6 depicts a flow diagram for an embodiment of a method of selective removal of a protective coating for a component that has an electrical contact region, which can be practiced using embodiments described herein.

### DETAILED DESCRIPTION

Various embodiments are described herein for materials processes, films, materials, coatings, components, machines, and more specifically a protective coating and/or an internal protective coating for a printhead for an inkjet printer, and variations thereof from which further embodiments are understood. Embodiments disclosed herein show improvements in multiple technologies, including film, coating, materials processing, and inkjet printer technology. Embodiments disclosed herein present a technological solution to the technological problem of how to protect, reduce damage and improve operating lifespan of inkjet printer printheads and other components subjected to inkjet printer ink or other acid or alkaline liquids. Description of research goals, findings and technology, starting below, is followed by description of the drawings, in order to convey to the reader various aspects, principles, advantages, and practical ways to make and use the various embodiments.

Among the coatings described herein are Advanced Coatings—IPC (Internal Protective Coating) and NWC (Non-Wetting Coating). The following description includes the use and deposition of HfO₂ (i.e., hafnia) coating and rationale(s) for choosing such a film, and alternatives to HfO₂, including ZrO₂, TiO₂, Ta₂O₅, SiCN, and various nitrides (described further below). There is description of method and application of coatings with higher-order assemblies (MEMS (microelectromechanical system)/IP (inkjet printhead)/HM), integration of NWC, including optimization of IPC for NWC adhesion, density, robustness, and optimization of NWC for inkjet, both method and application. In some embodiments, the coatings are deposited using atomic layer deposition (ALD). In some other embodiments, other types of deposition are used (e.g., chemical vapor deposition (CVD) and plasma-enhanced (PE)-CVD)).

Inkjet printheads can be fabricated using known micromachining techniques to produce highly precise and repeatable devices in large arrays. One of the best materials to create such accurate structures is silicon. It has excellent mechanical properties, and does not typically exhibit mechanical hysteresis at operating temperatures below 400° C. Silicon is highly resistant to attack by most acids. It can, however, be dissolved in solutions of sufficiently high-pH or in the presence of hydrofluoric acid (HF). Although it is not typical to jet HF, alkaline inks are quite common, and as such often exhibit attack of the silicon structure composing micromachined printheads. For this reason, it is desirable to protect any surfaces that would be wetted by these inks from such chemical attack, especially from alkaline chemistries.

One ideal protective layer (IPC) would have the following properties:
1) Highly resistant to chemical (especially alkaline) attack.
2) Robust to standard wafer fab handling.
3) Depositable in thin layers so as not to significantly impact precise dimensions or other performance criteria.
4) Depositable in dense layers so as not to allow attack of silicon or other structural components.
5) Highly conformal, so that no seams or cracks can be avenues of attack of silicon or other structural components.
6) Growth kinetics not overly sensitive to surface texture, so that nodules/whiskers/etc. do not create weak points for subsequent mechanical or chemical attack.
7) Uniform coating into small, relatively inaccessible spaces.
8) Integratable with the micromachining process—either near the end of the fabrication to coat all wetted surfaces OR on every layer of the printhead construction that may become wetted.
9) If implemented near the end of the fabrication flow, be depositable at sufficiently low temperature as to not adversely affect sensitive layers such as actuator, interconnect, or non-silicon constructive layers. These non-silicon materials may include, but are not limited to metals, organics, or ceramics.
10) Be compatible with additional layer functionality, e.g., non-wetting coating, either intrinsic or extrinsic.
11) Selectively removable to accommodate other processes (electrical interconnect, singulation, etch).
12) Not overly reactive to other constituent materials in the construction.
13) Allow adhesion of other desired materials including non-wetting coatings, primers, or other.

Atomic Layer Deposition (ALD), and similar related approaches, are a set of deposition techniques that exhibit many of the above desirable characteristics. They can be used to deposit several chemically resistant ceramic materials, in thin and dense layers that are highly conformal, and can be performed at temperatures that are compatible with the piezo-inkjet materials set. Given that there are many materials to consider, it is desirable to choose from among these materials for one that is superior. Prior investigations were performed by ceramicists to understand which materials might be highly resistant to chemical attack.

For example, K. Komeya and K. Nishida, Boshoku Gijutsu, 35, 646655 (1986) [in Japanese] divides a graph of radius of positive ion versus electric charge of positive ion, showing elements from the periodic table, into three regions:
I. React easily with acid
II. React or not with acid & alkali
III. React easily with alkali

“Hot corrosion of Al₂O₃ and SiC ceramics by KCl—NaCl molten salt”, Takaaki NAGAOKA,³ Ken' ichiro KITA and Naoki KONDO, technical report in Journal of the Ceramic Society of Japan 123 [8] 685-689 2015, discusses hot corrosion tests of alumina and carbon silicate ceramics.

In research for present embodiments, it was determined that, for materials more alkaline-resistant than SiO₂ and depositable in thin layers, candidates include ZrO₂, TiO₂, and Ta₂O₅. With an ionic radius of 0.83 Å, and ionic charge of +4, HfO₂ is also an excellent candidate for films deposited through ALD.

There are many possible flows, and one embodiment of process flow (with variations) includes a wafer construction with:
1) Internal cavities/plumbing to allow inflow and outflow of ink or other functional fluid, actuator(s), electrical and fluidic connection means (e.g., called here, inkjet wafer)
2) Deposition of IPC—selectively or not
3) IPC may be of a single material layer or multi-layer/multi-component stack of similar or dissimilar materials
4) Means to selectively exclude IPC—either through masking or removal, with or without selectivity to patterning or underlying layers
5) Surfaces suitable for additional coatings or functional modification, either:
6) intrinsic to the as-deposited film
7) extrinsically modified to allow additional coatings
8) compatible with additional intermediate coating (primer) that allows deposition of additional functional layer(s).

In research for embodiments disclosed herein, candidate oxide films were evaluated, including:
1) SiO₂—fair resistance to alkali
2) SiOC—fair resistance to alkali
3) ITO (indium tin oxide)—inconclusive
4) Al₂O₃—poor resistance to alkali without high-temperature anneal
5) ZrO₂—excellent resistance to alkali
6) HfO₂—best resistance to alkali of films studied
7) TiO₂—fair resistance to alkali
8) Ta₂O₅—good resistance to alkali
9) Y₂O₃—highly resistant to F plasma and other aggressive chemistries

Nitride films are also good candidates likely requiring plasma-enhanced deposition. These include but are not limited to:
1) SiCN—excellent resistance to alkali, but currently deposited at undesirably high temperature
2) TiN—excellent wear coating which is also conductive, thus useful for dissipating unwanted static electrification
3) TiCN—enhanced wear coating.

One example embodiment (with variations) includes:
I. A nearly completed wafer containing multiple printhead dies, each with arrays of jetting structures.
II. Openings that allow entry of reactive material into internal spaces that will ultimately contact ink in order to create protective coating. This protective coating is also on external surfaces, in various embodiments.
III. Deposition of IPC (e.g., HfO₂ coating single-component multi-layer stack) to reach coating thickness in range 10-50 nm
IV. Process (e.g., altered deposition conditions for outermost layers, plasma post-treatment, or ultra-thin coating of additional layer) to create priming layer, which allows subsequent functionalization (e.g., through silanization).
V. With option for selective removal of HfO₂ layer to reveal electrical interconnects or other structures through physical, chemical, or other means. Such a process may also be physically masked.

Higher order assemblies are discussed below. The micromachined silicon structure described above does not typically contain all the necessary functions for creating a printhead. For this reason, it is common to combine the micromachined inkjet wafer with other micromachined wafer strata that may include ink distribution, temperature measurement/control, fluidic and electrical interfaces, among other functions. These inkjet and other functional strata may be attached to one another through various means including bonding with metallic (e.g., solder) or organic attachment/structural materials (e.g., glue, adhesive, epoxy, etc.). These materials may also be susceptible to attack by inks and other functional fluids. For this reason, it is desirable to have an IPC coating which may be applied after bonding of various strata. It is also desirable that the IPC coating be generally compatible with these additional materials, for example to:
1) bond to attachment/structural layers so as not to permit attack of such layers by aggressive fluids.
2) be processed at a temperature that is compatible with such attachment/structural layers.
3) be adequately elastic so as to not fracture due to differential thermal expansion of constituent layers.
4) be impervious to liquid or vapor intrusion into underlying layers in order to prevent swelling, corrosion, or other structural detriments.

Additional Functional Layers (AFL) include, in various embodiments:

Intrinsic to the as-deposited film.
1) Modifying the deposition, especially near the end of film deposition, to increase the density of desirable terminal-groups. For HfO₂, this may include changing the mix to include H₂O and/or O₃ in the right ratio to increase the density of —OH terminations, which are binding sites for NWC chemistry. Note that the growth kinetics can be improved, and possibly optimized, to allow a more defect-free or denser layer.
   Extrinsically modified to allow additional coatings.
1) Subjecting the deposited film to additional treatment to promote formation of desired terminal-groups. For HfO₂, this may include ion milling (ion bombardment to create reactive/dangling bonds which then become hydrated), plasma treatment (changing O groups into —OH groups using H₂O, H₂/Ar, or other gases), etc.
2) Additional intermediate coating (primer) that allows deposition of additional functional layer.
3) Deposition of additional layers with higher densities of desired terminal-groups. These layers should be thick enough to create sufficient terminal-group density for site promotion, but thin enough to not be susceptible to lateral undercut, essentially allowing subsequent coating to become “unzipped” from the surface. For HfO₂, this could be Al₂O₃ or SiO₂ or similar hydrated material with —OH terminations, which are binding sites for NWC chemistry. In some embodiments, the additional layers include a wear coating (e.g., one or more nitrides) as well.

Characteristics of polymers are considered below, with impact on IPC and overall process. Polymers tend to degrade with heat more easily than many other suitable materials, with the possible exception of solders, which have intentionally low melting points, and which some embodiments exclude from pre-IPC construction. One piezoelectric actuator material (e.g., PZT, etc.) has been shown to degrade in performance at temperatures in excess of 280° C., especially in the presence of electric/magnetic fields. The temperature at which polymers degrade (e.g., shrink, expand, slump, reflow, embrittle, or crack) determines the upper temperatures at which some embodiments subsequently deposit an IPC or NWC film. One embodiment utilizes SU-8 (EPON photo-epoxy) in a MEMS die construction. SU-8 has glass transition temperature of 230° C., but does not change shape significantly at this temperature because of extensive cross-linking. Above this temperature, and especially approaching 270° C., larger shape changes or shrinkage will occur, which can put stress on other layers, and cause performance/reliability issues. For these reasons, one ALD deposition technique is attractive, as it can be deposited with high quality at temperatures <250° C., preferably at 230° C. or below. In a further embodiment, another process that can deposit at or below these temperatures, with good density/uniformity/conformality would be attractive. ALD seems to be uniquely capable of achieving all the objectives, but other approaches could be worth investigating and/or developing. In some other embodiments, different precursors that allow use of a lower temperature are used. In some additional embodiments, plasma-enhancement of a reactant or reactants is used.
1) Some embodiments involve plating of extra gold, and the specifics of are discussed below. One embodiment of a process flow includes: A wafer construction with internal cavities/plumbing to allow inflow and outflow of ink or other functional fluid, actuator(s), electrical and fluidic connection means (called here, inkjet wafer). Deposition of IPC—selectively or not.
2) IPC may be of a single material layer or multi-layer/multi-component stack of similar or dissimilar materials.
3) Processing to selectively exclude IPC—either through masking or removal, with or without selectivity to patterning or underlying layers.
4) Surfaces suitable for additional coatings or functional modification, e.g., either surfaces intrinsic to the as-deposited film or surfaces extrinsically modified to allow additional coatings, with such surfaces compatible with additional intermediate coating (primer) that allows deposition of additional functional layer(s).

In some embodiments, there is a need to remove IPC from the electrical connection areas of the jetting die for products that have electrical connection to the outside established via flex circuit and/or one or more methods, including, for example, flex, wire bonding, and soldering. This may not be the case in some embodiments with electrical connection established via wire bonding as it may be possible to bond through a thin coating due to mechanical impacts. This is similar to bonding Au wire bond to an Al bond pad, which has a thin AlO passivation layer. In some embodiments, this layer is broken up by scrubbing action at the bond, often with ultrasonic energy applied to the bond head. Some embodiments have one or both of two different electrical routing metallization schemes that have Au (gold) as the final coating because of its ability to establish reliable connections. Other metals (e.g., Pd, Pt, Nb, others) are possible. In some flex circuit embodiments, because there is soldering on to pads on the device, there is a restriction of the amount of Au on the pads because Au will dissolve into the solder melt, in turn causing the solder to become embrittled upon cooling, which will cause electrical connection reliability issues. However, if one process adds Au on the pads and another process removes all the Au on the pads, solder will not wet to the pad in some further process(es). This situation imposes constraints on both the amount of Au added on pads, and the amount of Au once added that is subsequently removed from pads, for example when removing IPC in electrical connection regions. These considerations are true for other interface materials besides Au as well.

In one embodiment, a process deposits IPC film(s) after the plumbing of the jetting die is open to the outside (through nozzles or ink fill ports), i.e., internal cavity(ies) are exposed for materials processing, which allows coating of all ink-contacted surfaces with IPC. Internal cavities being open/exposed for processing currently precludes utilization of wet chemistry to remove the IPC, as this would then remove IPC from the internal cavities where such coating is desired to remain in place. On the other hand, photopolymerizable films combined with efficient dry stripping is contemplated.

In one embodiment, IPC films (e.g., ALD oxides) are difficult to remove through selective chemical means, including in dry/plasma etching approaches. Inclusion of chlorine-containing etch species may make this easier. One method is to utilize ion milling with argon (i.e., Ar), which is a somewhat selective process. Unfortunately, selectivity is biased in the wrong direction, therefore Au is relatively more easily removed as compared to the ALD oxides. Polymers are not readily removed by this process. The ALD oxides are typically 30-50 nm in thickness, in one embodiment, and the selectivity of hafnia (i.e., HfO₂) to Au removal is about 3:1. That is, argon ion milling removes Au three times as easily as it removes HfO₂. Therefore, one embodiment with a 30-50 nm ALD oxide coating, including coating over electrical contact regions, has about 150 nm extra Au on pads (e.g., electrical contacts in this context) that can be removed (assuming 100% over-etch in argon ion milling), while leaving sufficient Au to ensure solderability of the pad. In this approach, a process thickens the Au layer in regions where the Au will be exposed to ion milling, and not in areas that are to remain covered by polymer passivation (Au is relatively expensive). This process has been demonstrated in one manufacturing environment.

The following description includes discussion around coating over plastic and what should occur in order to achieve success with the IPC, including example process steps. Plastic materials are attractive in printhead construction for several reasons, primary of which is that at the level of dimensional accuracy required for plumbing external to the Si die (e.g., headmount), molding allows relatively inexpensive implementation. Polymeric materials can vary in coefficient of thermal expansion (CTE) in the range of 15-75 ppm/C. Si, by comparison, has a CTE of 3 ppm/° C. Transfer molding of thermoset materials (e.g., EMC, CTE=10-12 ppm/° C.), used extensively in the semiconductor packaging application, is well-established and includes materials that are suitable for inkjet printhead construction. In one embodiment, SU-8 (CTE=55-60 ppm/° C.) is a plastic material used in the construction of printheads. Multiple Si strata, the headmount, and other elements exposed to ink are bonded together using ink-compatible epoxies (i.e., an example, glue, adhesive, etc.). If all Si parts are coated with IPC, they will be protected from, i.e., not be subject to, chemical attack. That means that the plastic elements become the weak link of any construction, in terms of such chemical attack. The ability to deposit IPC (e.g., HfO₂ bulk CTE=6.0 ppm/° C.) on the printhead construction at stages beyond the jetting die wafer-level is attractive for increasing the chemical resistance of the printhead. In various embodiments, IPC materials are brittle ceramics, which are typically stronger in compression than tension, but will fail with excessive loading. Given the above, being able to establish the chemically protective function of IPC at the lowest temperature possible is fundamental to achieving a reliable construction with an assortment of materials. ALD, e.g., using HfO₂ as described in various embodiments herein, allows creation of sufficient film density, uniformity, conformality, adhesion, and chemical-resistance for the inkjet application.

Further, on the embodiments that include coating over glue (e.g., to encapsulate the glue) or other bonding material, one main objective for IPC in this context is to coat at low temperature so as to avoid degradation of the glue, but with sufficient film performance. The printhead materials should be chosen such as to find the right balance of CTE, adhesion, and elastic modulus at full-cure (near zero remaining outgassing). Testing has confirmed coating over SU-8 films using various embodiments of this approach with excellent success. This has the implication that, provided a process includes selection of appropriate glues (e.g., DELO-OB787 w/ CTE=38 ppm/C @500 C, 72 ppm/° C. @ 150° C.), with sufficient adhesion, and the right cure schedule, a process can coat IPC over a variety of printhead construction materials while maintaining chemical resistance.

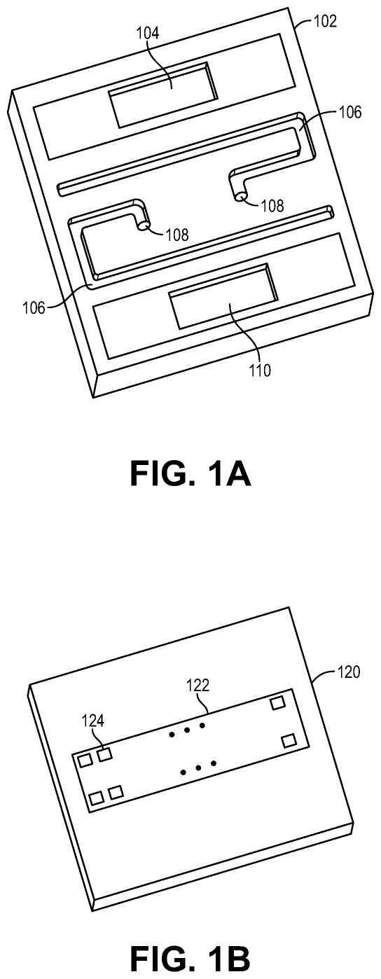

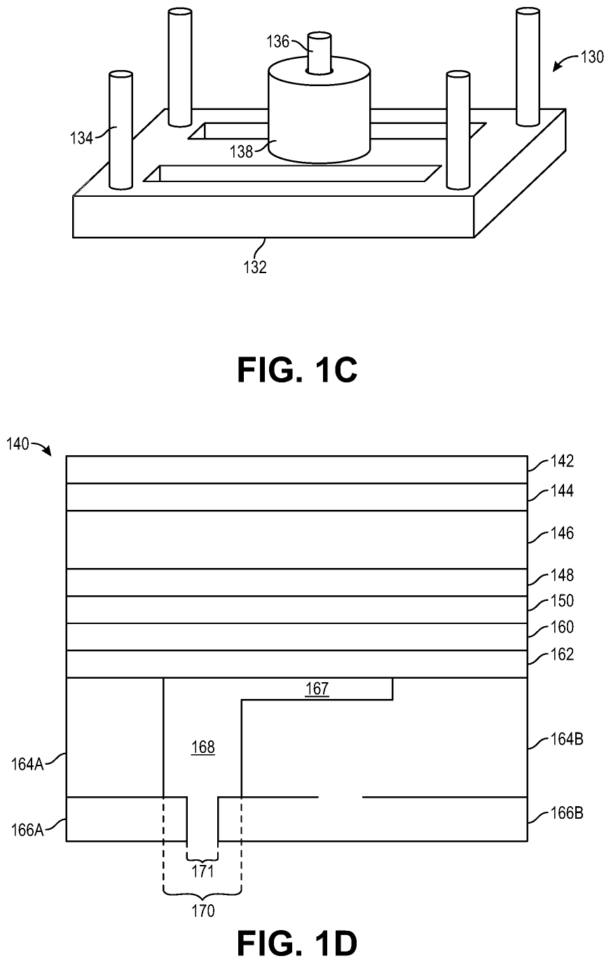

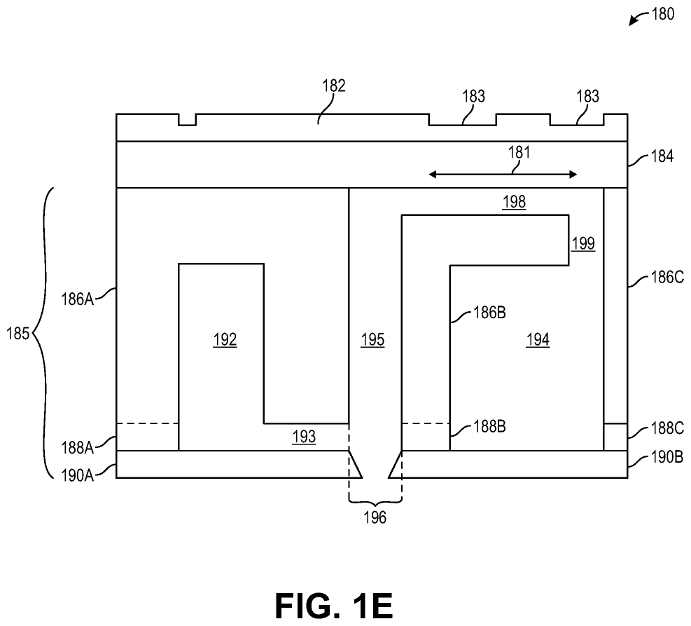

FIGS. 1A-1C depict components of an inkjet printer, as suitable for protective coating processes and materials described herein in various embodiments. One or more components could receive a coating prior to assembly with other components, or components could be coated in subassemblies of two or more components or completed assemblies of multiple components, in various combinations.

FIG. 1A depicts a head mount 102, which is a component of a printhead 130 (see FIG. 1C). The head mount 102 is made of thermoplastic in one embodiment, and has an open channel 106 with apertures 108, intended for use with printer ink. Further apertures 104, 108 support mounting of further components, for example transducers, ink supply fittings, or electrical connections. Channels 106 will be closed with assembly to one or more further components, which means there are multiple ways in which an internal cavity could be coated. One way is to coat the visible surface of the head mount 102, as seen in FIG. 1A, or coat the entirety of the head mount 102, in either case laying down a coating on the surface of the channels 106, which will be an internal surface of a cavity when the printhead is completed through assembly. Another way is to assemble two or more components of the printhead 130, including the head mount 102, such that the channel 106 becomes closed but with the apertures 108 exposing the internal cavity(ies) for processing, and then apply the coating with a process (e.g., atomic layer deposition) that spreads precursor gas through the apertures 108 into the internal cavity and coats a surface of the internal cavity.

FIG. 1B depicts a MEMS (microelectromechanical system) 122 die attached to a carrier 120, with ICs 124 mounted to the MEMS die, as a component of a printhead 130. For example, the ICs 124 could be mounted to the MEMS die by solder balls to make electrical connection. The MEMS 122 die could be attached to the carrier 120 also with solder balls, or wave soldering or other electrical connection technique. MEMS 122 die has transducers and nozzles. These could be supplemented with mechanical attachment, for example by glue or other bonding material. This assembled component could then be subjected to coating, in various embodiments, prior to further assembly with another component(s). Or, this assembled component could be assembled with one or more further components and then that assembly subjected to coating.

FIG. 1C depicts a printhead 130, which is built up through assembly including components depicted in FIGS. 1A and 1, as a component of an inkjet printer. For example, the head mount 102 has transducers 132, fluid port 134 (e.g., vent), ink reservoir 138 with fluid port 136 (e.g., vent) assembled together with glue and various electrical contacts made by solder balls, wave soldering, or other solder technique. The various components could be coated prior to such assembly, or the entire printhead 130 coated after assembly, in various embodiments. Internal cavities that are exposed for processing receive coating, for example through an aperture or a passage.

FIG. 1D depicts a cross section view of an example printhead 140, which is made of layers that define various features including an internal cavity and a nozzle 170. The layers can be of various materials, various construction and various shapes in various embodiments, and are not limited to the specific layers, construction and shapes described herein for an embodiment. Generalizing, there is more than one way and more than one set of materials that can be used to form a printhead with an internal cavity 168 and a nozzle 170. In the embodiment depicted in FIG. 1D, lead zirconium titanate (PZT) is an important material that possesses significant piezoelectric characteristics with its crystalline structures, and the layers are built up to form the printhead 140, as follows.

A lower electrode 150 and an adhesion layer 160 form the foundation of a lower electrode stack, which has a buffer PZT layer 148 on the adhesion layer 160. An epitaxial growth layer 146 physically contacting the buffer PZT layer 148, an adhesion layer 144 and an upper electrode 142 are upper layers in the structure depicted in the drawing. To the other side of the adhesion layer 160 (i.e., downward in the drawing), a deflection membrane 162 defines surfaces for the body 164A, 164B to adhere, and defines a surface of the cavity 168. Further surfaces of the cavity are defined by portions of the body 164A, 164B, which is made of a base wafer that defines an ink channel 167 and a pumping chamber 168 in one embodiment. A nozzle plate 166A, 166B adhered to the body 164A, 164B has an aperture 171, such that the structure defines a nozzle 170. Depending on viewpoint, the ink channel 167 and the pumping chamber 168 can each be considered, or can be considered in combination, as an internal cavity of the printhead 140. As such, the internal cavity and the nozzle 170 are intended to receive a protective coating. Surfaces of the internal cavity and the nozzle 170 are exposed through the nozzle 170, during materials processing, to receive a protective coating as described herein in various embodiments.

FIG. 1E depicts a cross section view of a further example printhead 180, which is made of layers that define an internal cavity and a nozzle. In this embodiment, an actuator 182 has trenches 183, and is attached to a support structure 184 that has a deformable portion 181. A substrate 185, which has various portions 186A, 188A, 186B, 188B, 186C, 188C arranged to define one or more cavities, is attached to the support structure 184 so that the deformable portion 181 of the support structure 184 can direct ink to exit through a nozzle 196 defined by an aperture in a nozzle plate 190A, 190B attached to the substrate 185. Portions 186A, 188A of the substrate 185 and the nozzle plate 190A further define an outlet feed channel 192 and outlet passage 193, which connect to a descender 195 leading to the nozzle 196. Portions 186A, 186B of the substrate 185, and a portion of the support structure 184 define the descender 195 and a pumping chamber 198, which connect to each other and to an ascender 197. The ascender 197 is defined by portions 186B, 186C of the substrate 185, and connects to the inlet feed channel 194 defined by portions 186B, 188B, 186 C, 188C of the substrate 185 and the nozzle plate 190B. By “connects” in this context, it is meant that the various chambers fluidly connect, for the containment, conveyance and/or dispensing of a fluid, specifically in this example, printer ink. Interior surfaces of these various chambers, including the outlet feed channel 192, outlet passage 193, inlet feed channel 194, ascender 197, pumping chamber 198, descender 195, and interior surface(s) of the nozzle 196, are intended to receive a protective coating, and are exposed through the nozzle 196, during materials processing, to receive a protective coating as described herein in various embodiments. Exterior surfaces, for example an exterior surface of the nozzle plate 190A, 190B may also receive such a protective coating. Further exterior surfaces of the printhead 180 may receive a protective coating, in embodiments where the protective coating is applied to exposed surfaces prior to assembly of the printhead to other component(s), which may obscure some surfaces and prevent such protective coating thereto.

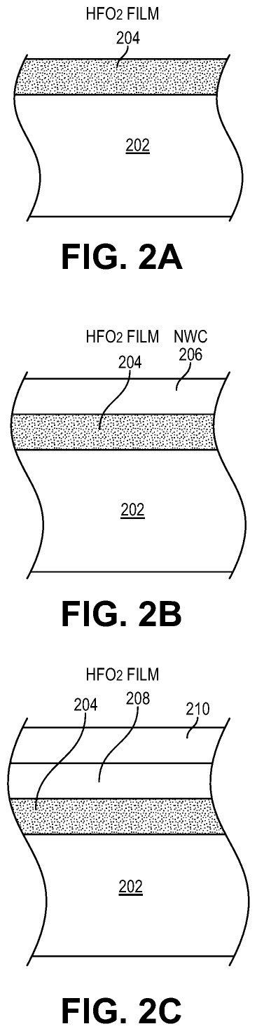

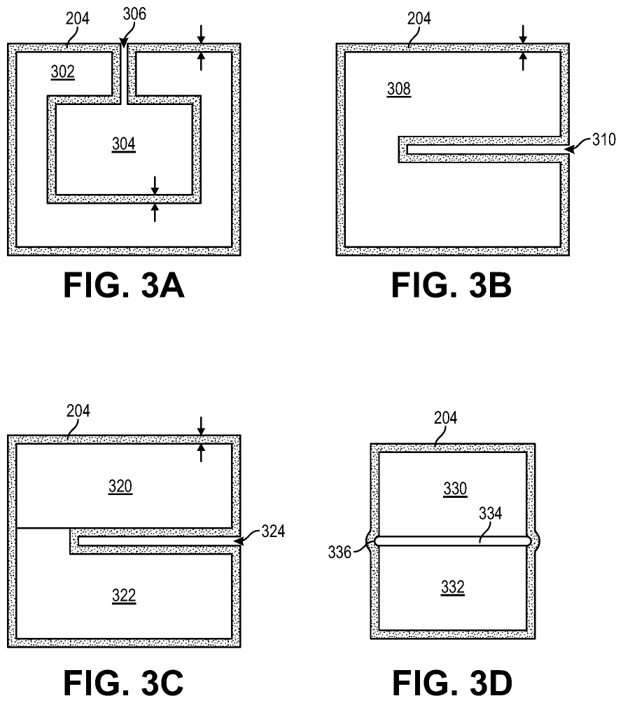

FIG. 2A depicts a coating 204 of HfO₂ on a component, in an embodiment. This is a cross section view, showing a cross section of the body 202, with a layer of HfO₂ film as the conformal coating on a surface of the body 202. It should be appreciated the diagram is intended to generalize, and other surfaces, depending on arrangement (e.g., in a deposition chamber) and exposure, could also have such a layer of HfO₂. This could include bottom, side, and internal (e.g., chamber) surfaces (see FIGS. 3A-3D).

FIG. 2B depicts a non-wetting coating (NWC) 206 on top of a coating 204 of HfO₂ on a component, in an embodiment. Various materials described herein could be used for the non-wetting coating 206, which is applied directly to, or atop, the HfO₂ film or coating 204 on the body 202 of the component. Other surfaces, such as bottom, side, and internal surfaces could also have these layers, again depending on arrangement and exposure. For an inkjet printer component, NWC coating 206 is advantageous with printer ink. In some embodiments, the NWC is on one film or coating from a group of various silanes with functional tail groups (e.g., perfluoro dodecyl trichloro silane (FDTS)) formed into a film on the film of HfO₂ or a layer resulting from a treatment applied to the film of HfO₂.

FIG. 2C depicts a multi-film coating on a component, in an embodiment. Various materials described herein could be applied between the non-wetting coating 210 and the film or coating 204 of HfO₂ on the body 202, to better adhere the non-wetting coating 210. For example, first to exit the printhead through a nozzle 196 the coating 204 of HfO₂ is applied on the body 202, next one or more layers of another material(s), including Al₂O₃ or SiO₂ in some embodiments, are applied as a coating 208 on top of the coating 204 of HfO₂, and a non-wetting coating 210 is applied on top of that coating 208. Other surfaces, such as bottom, side, and internal surfaces could also have these layers, again depending on arrangement and exposure.

FIGS. 3A-3D depict a cross section view of various components with a coating of HfO₂ on the component including coating an internal cavity, in embodiments. These cross section views are intended to be general to bodies and components, and could apply to components of printheads, components of inkjet printers, and components of other machines that would benefit from the protective coatings described herein in various embodiments.

FIG. 3A depicts a cross section view of a body 302 that has an internal cavity 304 exposed through a passage 306 for processing, with a conformal coating 204 of HfO₂. In various embodiments, the thickness of the conformal coating 204, indicated by opposing arrows, is about 30 nm, between 20 and 40 nm, between 30 and 50 nm, or between 10 and 50 nm, inclusive. These thicknesses, or ranges of thickness, are selected as target thickness for a process of applying the coating 204, so as to minimize or avoid formation of pinholes, thin spots (for thickness less than this) and nodule growth (for thickness greater than this). Determination of an optimal thickness for a conformal coating 204 may take experimentation for a given process and set of process parameters, and/or a given component and arrangement of cavity, and this should be straightforward and not undue experimentation. For example, tests (e.g., sample runs) could be run at trios of target thicknesses, for a minimum, medium and maximum thickness value and a given component.

FIG. 3B depicts a cross section view of a body 308 that has an internal cavity 310, for example a passage exposed for processing, with a conformal coating 204 of HfO₂. Precursor gas enters the internal cavity 310 from outside the body 308, and deposits the conformal coating 204 on a surface of the internal cavity 310. External surfaces of the body 308 are also coated with the conformal coating 204.

FIG. 3C depicts a cross section view of a body that is built up by assembling two bodies 320, 322 to each other, and which has an internal cavity 324 exposed for processing, with a conformal coating 204 of HfO₂. There are many processes applicable to assembling the two bodies 320, 322, to build up a body (e.g., a component), including mechanical assembly (e.g., with fasteners or press-fit), thermal (e.g., thermal bonding), chemical (e.g., chemical bonding, see also glue in FIG. 3D), etc. Routine testing of samples could determine suitability of a given component for coating, and see also description of optimal thickness of coating in FIG. 3A.

FIG. 3D depicts a cross section of a body that is built up by assembling two bodies 330, 332 to each other with glue 334, with a conformal coating 204 of HfO₂. Here, the conformal coating 204 is on exposed surface(s) of the assembled body, and also on an exposed portion 336 of glue 334. Glues as described herein are suitable, and other glues as well as these are readily tested with sample(s) and test runs that should be straightforward, and again not be undue experimentation. Note that other bonding material can be used in place of glue.

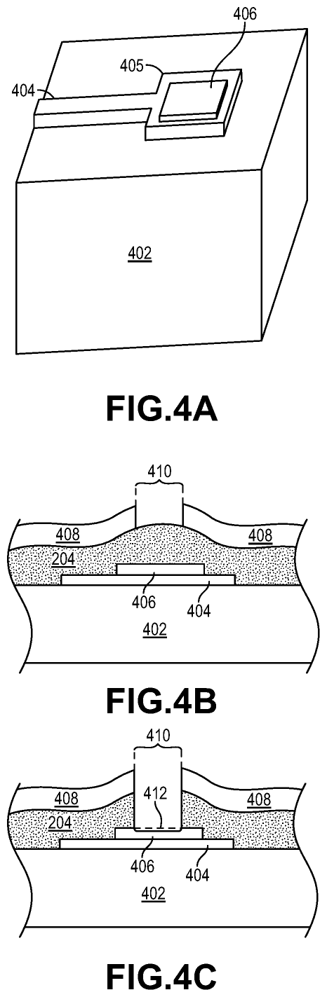

FIGS. 4A-4C depict a body 402 that has an electrical contact region, in embodiments. For example, an electrical contact region is a region to which a solder ball, solder paste or other form of solder will be applied in order to electrically connect electrical or electronic circuitry of one component to electrical or electronic circuitry of another component. In these embodiments, the electrical contact is made to an electrical contact pad 405, with gold 406, which is exposed for application of solder in appropriate form.

FIG. 4A depicts a body 402 that has an electrical contact pad 405 with gold 406 atop another metal. For example, the pad 405 and wire 404 leading to or from the pad 405 could be formed of aluminum, copper or other electrical conducting metal, on a surface of the body 402. For example, the body 402 could be a printed circuit board, flexible circuit board, a carrier, a multichip assembly on a substrate, thermoset plastic, or other component or material suitable for supporting electrical contact pad 405 for electrical connection thereto. It is intended, in these embodiments, to apply a conformal coating 204 of HfO₂, to protect as much of the body 402 as possible or as designated, but have exposure of the electrical contact region(s) for soldering.

FIG. 4B depicts a cross section view of the embodiment in FIG. 4A, with a conformal layer or coating 204 of HfO₂ on the surface of the body 402, including over the electrical contact region, and a mask 408 defining a selective removal region 410. The coating 204 is applied as in various embodiments described herein, to a suitable thickness as described herein. Mask 408 is arranged, for example through applied photoresist that is UV (ultraviolet light) exposed and removed according to a defined pattern in the UV exposure, or electron-beam defined, or other masking process used in industry. Mechanical masks, for example laser cut silicon, are contemplated. Whichever mask is used aligns the selective removal region 410 with the gold 406 and the pad 405 to which electrical contact by soldering is intended. Removed portion(s) of the mask 408 expose a surface of the coating 204 in the selective removal region 410, for removal, e.g., by ion milling. Remaining portion(s) of the mask 408 protects the remaining surface of the coating 204, which is not then removed, e.g., by such ion milling.

FIG. 4C depicts a cross section view of the embodiment in FIG. 4A, after further processing since the cross section view in FIG. 4B, showing selective removal of a portion of the HfO₂ conformal coating 204 in the electrical contact region 410, with partial removal of a portion 412 of the gold 406 on the electrical contact pad 405. In some embodiments, ion milling is applied with an adjusted amount of overetch, for example 50-150% overetch, so that all of the HfO₂ above the gold 406 and pad 405 in the electrical contact region 410 is removed. However, because some of the gold 406 (e.g., the portion 412 of the gold 406, indicated by the dashed line) will also be removed by ion milling, the amount of extra gold that is added on top of the electrical contact pad 405 is adjusted according to the thickness of HfO₂ and amount of time for ion milling to remove that thickness, allowing for overetch. The minimum amount of gold 406 added on top of the electrical contact pad 405 is determined by the overetch, and the maximum amount of gold 406 added on top of the electrical contact pad 405 is determined by avoiding embrittlement of solder. In one embodiment, the thickness of HfO₂ is in a range of 20 to 40 nm, and the amount of extra gold added on top of the pad 405 is about 150 nm, so that the total thickness of gold 406 on the electrical contact pad 405 is greater than 170 nm. Note that the drawing is not to scale. In some other embodiments, the amount of gold that is used is enough to prevent oxidation (and enable solder wetting) yet be sufficient thin to prevent solder-Au embrittlement.

In some embodiments, there is a non-selective process in which no masking is used and ion milling can remove the entire coating from one external surface (or more) of a wafer and/or component. Such non-masking is used for cases in which the surfaces are not expected to be exposed to attack by fluid.

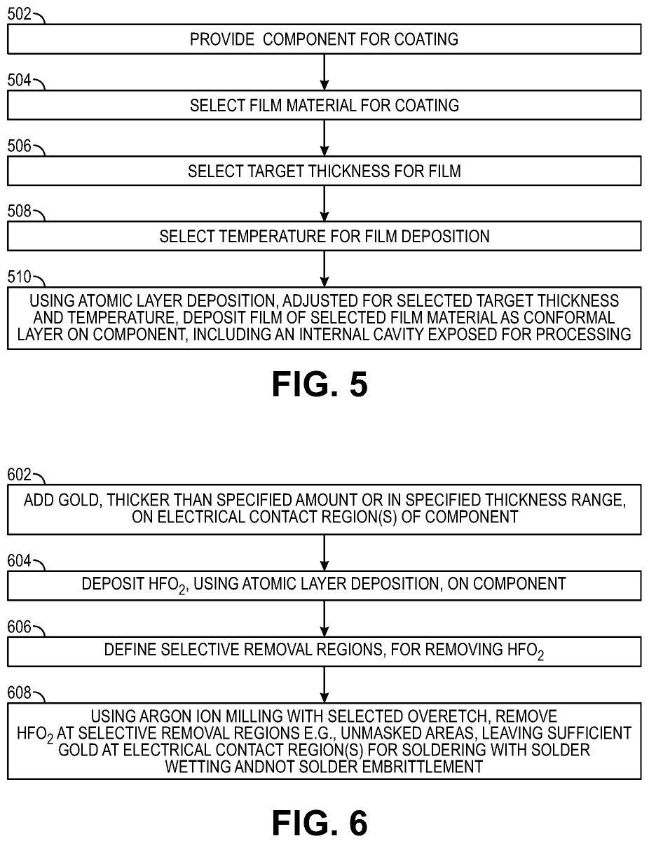

FIG. 5 depicts a flow diagram for an embodiment of method of making a protective coating for a component, which can be practiced using embodiments described herein. The method can be practiced using a machine that performs atomic layer deposition, precursor gas for HfO₂, and various components including components for inkjet printers and components for inkjet printheads. In further embodiments, the method can be practiced using candidate oxide films and candidate nitride films with various characteristics as described herein.

In an action 502, a component is provided for coating. For example, a component of an inkjet printhead, a printhead assembly or subassembly, or a component of an inkjet printer could be used. The component could be manufactured in-house, or sourced externally and brought in for further processing. In various embodiments, the component has at least one internal cavity that is accessible for processing. In various embodiments, the component is to be exposed to an acid or alkali liquid during usage of a machine. For example, the liquid could be printer ink.

In an action 504, a film material is selected for a coating. In various embodiments described herein, the film material is HfO₂, to be made as a conformal coating using atomic layer deposition.

In an action 506, a target thickness is selected for the film. In various embodiments described herein, the target thickness for a film of HfO₂ is between 10 and 50 nm, between 20 and 40 nm, between 30 and 50 nm, or about 30 nm. The target thickness is selected to avoid formation of pinholes, thin spots and nodule growth. In some embodiments in which laser dicing is to be used, the thickness of HFO₂ is maintained below 50 nm.

In an action 508, a temperature is selected for film deposition. In various embodiments described herein, the temperature is suitable for film deposition on thermoset and/or on glue (or other bonding material). In some embodiments, the selected temperature is in a range between 185° C. and 275° C., inclusive.

In an action 510, using atomic layer deposition, adjusted for the selected target thickness and selected temperature, a film of the selected film material is deposited as a conformal layer on the component, including on an internal cavity exposed for processing.

The method can be varied with additional actions, for example to deposit additional films (e.g., NWC coating) as described herein.

FIG. 6 depicts a flow diagram for an embodiment of a method of selective removal of a protective coating for a component that has an electrical contact region, which can be practiced using embodiments described herein. Especially, the method depicted in FIG. 6 can be combined with the method depicted in FIG. 5, to produce a component that has a protective coating with openings for electrical contact.

In an action 602, gold, thicker than a specified amount or in a specified thickness range, is added on electrical contact region(s) of a component. For example, in some embodiments, at least 200 nm of gold, or gold thicker than 200 nm (e.g., gold thicker than 300 nm), or gold in a range of 220-240 nm is added on top of a contact pad of a component. In some other embodiments, a lower amount of gold can be used. The amount of gold is specified as an amount that will leave some gold (enough for solder wetting, but not too much so that solder becomes embrittled) on the contact pad after ion milling with over etch removes HfO₂ film or coating in a defined electrical contact region.

In an action 604, a conformal film, layer or coating of HfO₂ is deposited on the component, using atomic layer deposition (see, e.g., method in FIG. 5). The target thickness, or a measured thickness, of the coating should be made available for use in determining the processing parameter(s), e.g., etch time including overetch, in the action 608.

In an action 606, in some embodiments, selective removal regions are defined, for removing HfO₂. For example, a mask, photoresist, physical masking, etc., is used to expose a portion of the HfO₂ and shield the remainder of the HfO₂ from removal. The selective removal regions should align with electrical contact regions of the component.

In an action 608, using argon ion milling with selected overetch, HfO₂ is removed at selective removal regions, leaving sufficient gold at electrical contact region(s) for soldering with solder wetting and not solder embrittlement.

There are a number of example embodiments described herein.

Example 1 is a method of making a material for an article, comprising: providing a component of a machine, wherein the component has at least one internal cavity accessible for processing, and wherein the component is to be exposed to an acid liquid, an alkali liquid, or another liquid that chemically attacks the component during usage of the machine; selecting a target thickness for a film of HfO2 that will avoid formation of pinholes, thin spots and nodule growth; and using atomic layer deposition (ALD) with the processing adjusted for the target thickness, depositing the film of HfO2 as a conformal layer on the component, including on a surface of the at least one internal cavity, to form a coated component, wherein the material comprises the deposited film of HfO2 as a protective coating.

Example 2 is the method of claim 1 that may optionally include that the target thickness is between 10 nm and 50 nm, inclusive.

Example 3 is the method of claim 1 that may optionally include that the target thickness is between 20 nm and 40 nm, inclusive.

Example 4 is the method of claim 1 that may optionally include that the depositing the film of HfO2 is performed in a temperature range between 185° C. and 275° C., inclusive.

Example 5 is the method of claim 1 that may optionally include that the component is a member of an inkjet printhead; the acid the alkali liquid, or the liquid that chemically attacks the component is printer ink; and the material acts as the protective coating of the component against the printer ink.

Example 6 is the method of claim 1 that may optionally include that the component comprises multiple members bonded and/or constructed together with a bonding material; and the depositing the film of HfO2 includes depositing on an exposed portion of the bonding material.

Example 7 is the method of claim 6 that may optionally include that the bonding material comprises at least one selected from a group that comprises: glue, epoxy, adhesive, solder, and photoresist.

Example 8 is the method of claim 1 that may optionally include adhering a non-wetting coating (NWC) to the deposited film of HfO2, wherein the material comprises the deposited film of HfO2 with the adhered non-wetting coating.

Example 9 is the method of claim 1 that may optionally include depositing at least one from a group consisting of Al₂O₃ or SiO₂, on the deposited film of HfO2, and depositing a non-wetting coating (NWC) on the deposited at least one from the group.

Example 10 is the method of claim 1 that may optionally include using ion milling, selectively removing portions of the deposited film of HfO2, to expose a surface comprising gold or other conductive material suitable for electrical interconnect.

Example 11 is the method of claim 1 that may optionally include shielding a first portion of the component using a physical mask having at least one aperture to expose a second portion of the coated component; and using ion milling to remove a portion of the deposited film of HfO2 from the exposed second portion of the coated component.

Example 12 is the method of claim 1 that may optionally include that the component includes a plurality of electrical contact regions each comprising gold, the method further comprising: using argon ion milling with over etch between 50%-150%, inclusive, selectively removing portions of the deposited film of HfO2, each having a thickness between 10 nm and 50 nm, to expose each of the plurality of electrical contact regions, wherein the over etch removes a portion of gold at each of the plurality of electrical contact regions.

Example 13 is the method of claim 1 that may optionally include that the component includes at least one portion of thermoset plastic; and wherein the depositing the film of HfO2 is performed in a temperature range below a damage temperature of the thermoset.

Example 14 is the method of claim 1 that may optionally include that the component includes at least one portion of polymeric material, wherein the depositing of the film of HfO2 is performed in a temperature range below which the polymeric material degrades structurally.

Example 15 is a method of making a material for an article, comprising: depositing metal on a plurality of electrical contacts of a component of a machine, wherein the component has at least one internal cavity accessible for processing, and wherein the component is to be exposed to an acid, alkali, or another chemically attacking liquid during usage of the machine; selecting a target thickness for a film, the film being HfO2, ZrO₂, TiO₂, or a chemically resistant oxide or nitride; depositing the film as a conformal layer on the component at the target thickness, including on a surface of the at least one internal cavity and the metal on the electrical contacts, to form a coated component, wherein the material comprises the deposited film as a protective coating; and selectively removing/excluding portions of the deposited film, to expose the metal over the plurality of electrical contacts.

Example 16 is the method of claim 15 that may optionally include that the metal comprises gold, copper, or nickel.

Example 17 is the method of claim 15 that may optionally include adhering a non-wetting coating (NWC) to the deposited film, wherein the material comprises the deposited film with the adhered non-wetting coating.

Example 18 is the method of claim 15 that may optionally include depositing at least one from a group consisting of Al₂O₃ or SiO₂, on the deposited film, and depositing a non-wetting coating (NWC) on the deposited film.

Example 19 is the method of claim 15 that may optionally include using ion milling for removing the portions of the deposited film.

Example 20 is the method of claim 15 that may optionally include shielding a first portion of the component using a physical mask having at least one aperture to expose a second portion of the coated component, and using ion milling to remove a portion of the deposited film from the exposed second portion of the coated component.

Example 21 is the method of claim 15 that may optionally include using argon ion milling with over etch between 50%-150%, inclusive, removing portions of the deposited film, each having a thickness between 10 nm and 50 nm, to expose each of the plurality of electrical contact regions, wherein the over etch removes a portion of gold at each of the plurality of electrical contact regions.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein. It should be appreciated that descriptions of direction and orientation are for convenience of interpretation, and the apparatus is not limited as to orientation with respect to gravity. In other words, the apparatus could be mounted upside down, right side up, diagonally, vertically, horizontally, etc., and the descriptions of direction and orientation are relative to portions of the apparatus itself, and not absolute.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” perform a task or tasks. In such contexts, the phrase “configured to” is used to connote structure by indicating that the units/circuits/components include structure (e.g., circuitry or mechanical features) that performs the task or tasks during operation. As such, the unit/circuit/component can be said to be configured to perform the task even when the specified unit/circuit/component is not currently operational (e.g., is not on). The units/circuits/components used with the “configured to” language include hardware—for example, circuits, memory storing program instructions executable to implement the operation, etc. Reciting that a unit/circuit/component is “configured to” perform one or more tasks is expressly intended not to invoke 35 U.S.C. 112, sixth paragraph, for that unit/circuit/component. Additionally, “configured to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits or manufactured articles) that are adapted to implement or perform one or more tasks, or designing an article or apparatus to have certain features or capabilities.

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A method of making a material for an article, comprising:
providing a component of a machine, wherein the component has at least one internal cavity accessible for processing, and wherein the component is to be exposed to an acid liquid, an alkali liquid, or another liquid that chemically attacks the component during usage of the machine;
selecting a target thickness for a film of HfO₂ that will avoid formation of pinholes, thin spots and nodule growth; and
using atomic layer deposition (ALD) with the processing adjusted for the target thickness, depositing the film of HfO₂ as a conformal layer on the component, including on a surface of the at least one internal cavity, to form a coated component, wherein the material comprises the deposited film of HfO₂ as a protective coating.

2. The method of claim 1, wherein the target thickness is between 10 nm and 50 nm, inclusive.

3. The method of claim 1, wherein the target thickness is between 20 nm and 40 nm, inclusive.

4. The method of claim 1, wherein the depositing the film of HfO₂ is performed in a temperature range between 185° C. and 275° C., inclusive.

5. The method of claim 1, wherein:
the component is a member of an inkjet printhead;
the acid the alkali liquid, or the liquid that chemically attacks the component is printer ink; and
the material acts as the protective coating of the component against the printer ink.

6. The method of claim 1, wherein:
the component comprises multiple members bonded and/or constructed together with a bonding material; and
the depositing the film of HfO₂ includes depositing on an exposed portion of the bonding material.

7. The method of claim 6 wherein the bonding material comprises at least one selected from a group that comprises: glue, epoxy, adhesive, solder, and photoresist.

8. The method of claim 1, further comprising:
adhering a non-wetting coating (NWC) to the deposited film of HfO₂, wherein the material comprises the deposited film of HfO₂ with the adhered non-wetting coating.

9. The method of claim 1, further comprising:
depositing at least one from a group consisting of Al₂O₃ or SiO₂, on the deposited film of HfO₂; and
depositing a non-wetting coating (NWC) on the deposited at least one from the group.

10. The method of claim 1, further comprising:
using ion milling, selectively removing portions of the deposited film of HfO₂, to expose a surface comprising gold or other conductive material suitable for electrical interconnect.

11. The method of claim 1, further comprising:
shielding a first portion of the component using a physical mask having at least one aperture to expose a second portion of the coated component; and
using ion milling to remove a portion of the deposited film of HfO₂ from the exposed second portion of the coated component.

12. The method of claim 1, wherein the component includes a plurality of electrical contact regions each comprising gold, the method further comprising:
using argon ion milling with over etch between 50%-150%, inclusive, selectively removing portions of the deposited film of HfO₂, each having a thickness between 10 nm and 50 nm, to expose each of the plurality of electrical contact regions, wherein the over etch removes a portion of gold at each of the plurality of electrical contact regions.

13. The method of claim 1, wherein:
the component includes at least one portion of thermoset plastic; and
wherein the depositing the film of HfO₂ is performed in a temperature range below a damage temperature of the thermoset.

14. The method of claim 1, wherein:
the component includes at least one portion of polymeric material; and
the depositing of the film of HfO₂ is performed in a temperature range below which the polymeric material degrades structurally.

15. A method of making a material for an article, comprising:
depositing metal on a plurality of electrical contacts of a component of a machine, wherein the component has at least one internal cavity accessible for processing, and wherein the component is to be exposed to an acid, alkali, or another chemically attacking liquid during usage of the machine;
selecting a target thickness for a film, the film being HfO₂, ZrO₂, TiO₂, or a chemically resistant oxide or nitride;
depositing the film as a conformal layer on the component at the target thickness, including on a surface of the at least one internal cavity and the metal on the electrical contacts, to form a coated component, wherein the material comprises the deposited film as a protective coating; and
selectively removing/excluding portions of the deposited film, to expose the metal over the plurality of electrical contacts.

16. The method of claim 15, wherein the metal comprises gold, copper, or nickel.

17. The method of claim 15, further comprising:
adhering a non-wetting coating (NWC) to the deposited film, wherein the material comprises the deposited film with the adhered non-wetting coating.

18. The method of claim 15, further comprising:
depositing at least one from a group consisting of Al₂O₃ or SiO₂, on the deposited film; and
depositing a non-wetting coating (NWC) on the deposited film.

19. The method of claim 15, further comprising:
using ion milling for removing the portions of the deposited film.

20. The method of claim 15, further comprising:
shielding a first portion of the component using a physical mask having at least one aperture to expose a second portion of the coated component; and
using ion milling to remove a portion of the deposited film from the exposed second portion of the coated component.

21. The method of claim 15, further comprising:
using argon ion milling with over etch between 50%-150%, inclusive, removing portions of the deposited film, each having a thickness between 10 nm and 50 nm, to expose each of the plurality of electrical contact regions, wherein the over etch removes a portion of gold at each of the plurality of electrical contact regions.
